(19) United States
(12) Patent Application Publication
(10) Pub. No.: US 2018/0366637 A1
(43) Pub. Date: Dec. 20, 2018

(54) CORROSION RESISTANT MAGNETORESISTIVE SENSOR

(71) Applicant: Littelfuse, Inc., Chicago, IL (US)

(72) Inventors: Martin G. Pineda, Fremont, CA (US); Yuriy B. Matus, Pleasanton, CA (US)

(21) Appl. No.: 16/009,709

(22) Filed: Jun. 15, 2018

Related U.S. Application Data
(60) Provisional application No. 62/519,980, filed on Jun. 15, 2017.

(51) Int. Cl. H01L 43/02; H01L 43/08; H01L 43/10; H01L 43/12; G01R 33/09; G01R 33/00

(52) U.S. Cl. CPC H01L 43/02; H01L 43/08; H01L 43/10; G01R 33/0047; G01R 33/09; G01R 33/0052; H01L 43/12

(57) ABSTRACT

A corrosion resistant magnetoresistive sensor including an electrically insulating substrate, an electrically conductive first terminal disposed on a first end of the substrate, an electrically conductive second terminal disposed on a second end of the substrate, a plurality of nanowires disposed on the substrate between the first terminal and the second terminal, and an oxygen barrier composition covering the nanowires and protecting the nanowires from oxygen and moisture.

### CROSS REFERENCES TO RELATED APPLICATIONS

This application claims the benefit of U.S. Provisional Patent Application No. 62/519,980, filed Jun. 15, 2017, which is incorporated by reference herein in its entirety.

### FIELD OF THE DISCLOSURE

The disclosure relates generally to the field of magnetoresistive sensors, and more particularly to magnetoresistive sensor elements with corrosion resistant coatings and methods for forming the same.

### BACKGROUND OF THE DISCLOSURE

Magnetoresistance (MR) is the property of a material to change its electrical resistance in response to the presence of a magnetic field. Magnetic sensors based on the MR effect, commonly referred to as “magnetoresistive sensors” or “MR sensors,” can measure the strengths of magnetic fields and/or the relative orientations of such fields. One of the most significant applications of MR sensors is their incorporation into read heads of magnetic recording devices. Five distinct types of MR that are commonly employed in MR sensors are ordinary magnetoresistance (OMR), anisotropic magnetoresistance (AMR), giant magnetoresistance (GMR), tunneling magnetoresistance (TMR), and colossal magnetoresistance (CMR).

In some embodiments, the active sensing elements in MR sensors are nano-particles or nanowires formed of alternating layers of magnetic and non-magnetic materials, usually metals. The nano-particles or nanowires are typically suspended or dispersed in a carrier liquid that facilitates deposition on of the nano-particles or nanowires on a substrate, such as via printing or spraying. The carrier liquid may include binders or other additives to achieve desired fluid characteristics, such as a desired viscosity.

One shortcoming associated with metal-based MR sensors, especially those that include nano-particle or nano-wire sensing elements, is the susceptibility of nano-dimensioned elements to galvanic corrosion, which occurs due to the multi-metal construction of nanowires and the inevitable exposure of nanowires to electrolytes or oxidizers (e.g., water, oxygen, etc.). Nano-particles and nanowires that experience galvanic corrosion may develop surface roughness, variations in interlayer thicknesses, and surface oxidation, all of which may contribute to the degradation of MR sensor sensitivity over time.

It is with respect to these and other considerations that the present disclosure is provided.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

An exemplary embodiment of a corrosion resistant MR sensor in accordance with the present disclosure may include an electrically insulating substrate, an electrically conductive first terminal disposed on a first end of the substrate, an electrically conductive second terminal disposed on a second end of the substrate, a plurality of nanowires disposed on the substrate between the first terminal and the second terminal, and an oxygen barrier composition covering the nanowires and protecting the nanowires from oxygen and moisture.

An exemplary embodiment of a method for forming a corrosion resistant MR sensor in accordance with the present disclosure may include providing an electrically insulating substrate, connecting an electrically conductive first terminal to a first end of the substrate, connecting an electrically conductive second terminal to a second end of the substrate, disposing a plurality of nanowires on the substrate between the first terminal and the second terminal, and covering the nanowires with an oxygen barrier composition that protects the nanowires from oxygen and moisture.

### BRIEF DESCRIPTION OF THE DRAWINGS

FIG. 1a is a side view illustrating a corrosion resistant MR sensor in accordance with an exemplary embodiment of the present disclosure;

FIG. 1b is a top view illustrating the corrosion resistant MR sensor shown in FIG. 1a.

### DETAILED DESCRIPTION

A corrosion resistant magnetoresistive (MR) sensor and a method of forming the same in accordance with the present disclosure will now be described more fully hereinafter with reference to the accompanying drawings, in which a preferred embodiment of the MR sensor and the associated method are presented. The MR sensor and associated method may, however, be embodied in many different forms and should not be construed as being limited to the embodiments set forth herein. Rather, these embodiments are provided so that this disclosure will convey certain exemplary aspects of the MR sensor and the associated method to those skilled in the art.

In general, the MR sensor of the present disclosure includes active sensing elements (i.e., nanowires) that are coated or covered with an epoxy-based solution that provides an oxygen and moisture barrier. The nanowires are thus protected against galvanic corrosion, thereby preserving the sensitivity of the MR sensor over time.

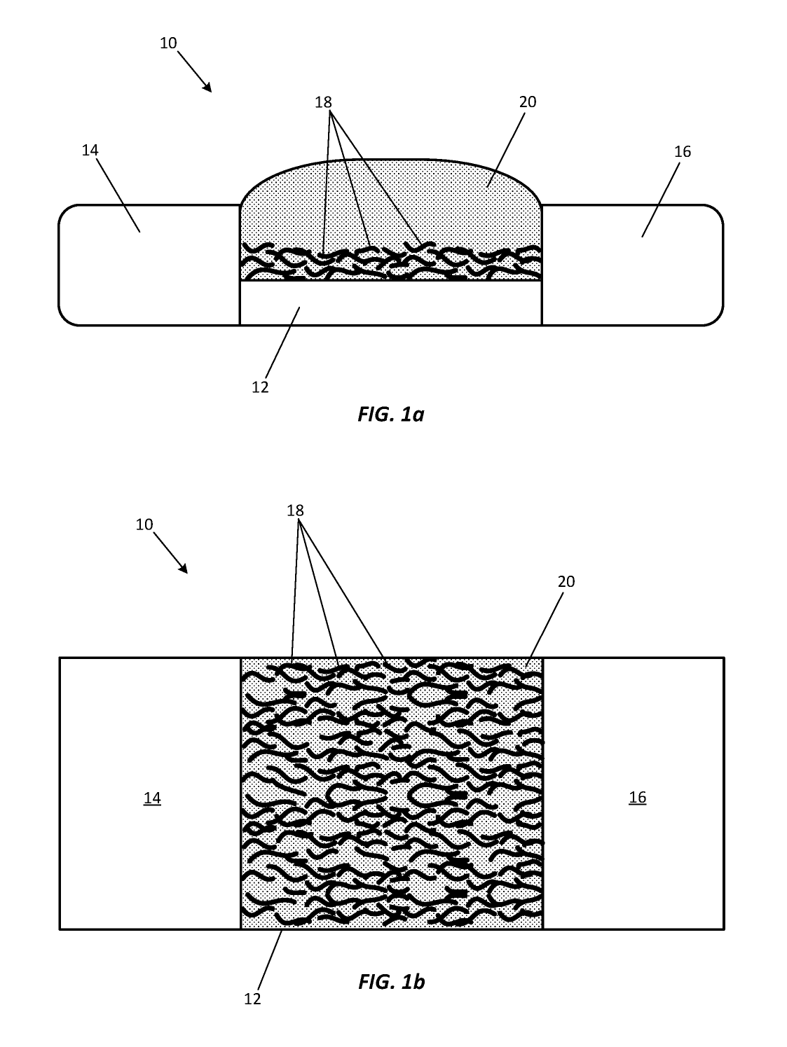

FIGS. 1a and 1b respectively illustrate side and top views of a corrosion resistant MR sensor 10 (hereinafter “the MR sensor 10”) in accordance with an exemplary embodiment of the present disclosure. The MR sensor 10 may include an electrically insulating substrate 12, electrically conductive terminals 14, 16 fastened to opposing ends of the substrate 12, and a plurality of nano-particles or nanowires 18 (hereinafter collectively referred to as nanowires 18) disposed on the substrate 12 and providing an electrically conductive pathway (or a plurality of electrically conductive pathways) between the terminals 14, 16. The substrate 12 may be formed any suitable, electrically insulating material, including, but not limited to, FR-4, ceramic, Alumina, Mylar, etc. The terminals 14, 16 may be formed of any suitable, electrically conductive material, including, but not limited to, silver, copper, aluminum, etc.

The nanowires 18 may be giant magnetoresistive (GMR) nanowires constructed from alternating ferromagnetic and non-magnetic conductive layers. In certain exemplary embodiments, the ferromagnetic conductive layers are less than 100 nm (e.g., 15 nm) in thickness and the non-magnetic conductive layers are less than 50 nm (e.g., 5 nm) in thickness, though it will be understood that the present disclosure is not limited in this regard and that the dimensions of the nanowires 18 may be varied to suit particular applications. The nanowires 18 may include at least 2 alternating ferromagnetic and non-magnetic conductive layers, and more typically will include tens, hundreds, or even thousands of alternating layers. While many embodiments of the nanowires 18 will have at least 5, 10, 25, or 50 alternating layers, certain embodiments could have fewer alternating layers. Exemplary compounds that may be used to form the ferromagnetic layers may include, but are not limited to, Co, CoFe, CoNiFe, CoNi, CoNiFeCr, CoCr, CoNiCr, NiFe, NiCo, or NiCoCr. Exemplary materials that may be used to form the non-magnetic conductive layers include, but are not limited to, Cu, Ag, Au or alloys of these metals.

Instead of GMR nanowires, it is contemplated that the nanowires 18 of the present disclosure may, in various alternative embodiments of the MR sensor 10, be ordinary magnetoresistance (OMR) nanowires, anisotropic magnetoresistance (AMR) nanowires, tunneling magnetoresistance (TMR) nanowires, or colossal magnetoresistance (CMR) nanowires, for example. It is further contemplated that the nanowires 18 may be replaced by micro-sized wires or whiskers without departing from the present disclosure.

Prior to being deposited on the substrate 12, the nanowires 18 may be suspended or dispersed in a carrier liquid to facilitate application to the substrate 12 via spraying, printing etc. Typically, the nanowires 18 are at least temporarily suspended in the carrier fluid. However, the nanowires 18 only need remain suspended long enough to be applied to the substrate material. Preferably, the carrier fluid should be homogeneous, i.e., the nanowires 18 should be suspended uniformly or nearly uniformly in the carrier solution. Any number of fluids may be used as the nanowire carrier fluid. For example, any non-corrosive liquid in which the nanowires 18 can form a stable dispersion may be used. Preferably, the nanowires 18 are dispersed in water, an alcohol, a ketone, ethers, hydrocarbons or an aromatic solvent (benzene, toluene, xylene, etc.). More preferably, the liquid is volatile, having a boiling point of no more than 200° C., no more than 150° C., or no more than 100° C.

In addition, the nanowire carrier fluid (or “dispersion”) may contain binders and other additives to control viscosity, corrosion, adhesion, and nanowire dispersion. A binder may be any material or substance that holds or draws other materials together to form a cohesive whole. Binders may include gelling or thickening agents along with viscosity modifiers. Examples of suitable binders include, but are not limited to, carboxy methyl cellulose (CMC), 2-hydroxy ethyl cellulose (HEC), hydroxy propyl methyl cellulose (HPMC), methyl cellulose (MC), poly vinyl alcohol (PVA), tripropylene gylcol (TPG), and xanthan gum (XG).

Examples of suitable viscosity modifiers include biopolymers, such as hydroxypropyl methyl cellulose (HPMC), methyl cellulose, xanthan gum, tragacanth gum, carboxy methyl cellulose, and hydroxy ethyl cellulose; acrylic polymers, such as, sodium polyacrylate; and water-soluble synthetic polymers, such as, polyvinyl alcohol.

The carrier fluid may also contain surfactants. Surfactants are compounds that lower the surface tension of a liquid, the interfacial tension between two liquids, or that between a liquid and a solid. Surfactants may act as detergents, wetting agents, emulsifiers, foaming agents, and dispersants. Examples of surfactants may include ethoxylates, alkoxylates, ethylene oxide and propylene oxide and their copolymers, sulfonates, sulfates, disulfonate salts, sulfosuccinates, phosphate esters, and fluorosurfactants (e.g., Zonyl® by DuPont). More particular examples of suitable surfactants include Zonyl® FSN, Zonyl® FSO, Zonyl® FSH, Triton (x100, x114, x45), Dynol (604, 607), n-Dodecyl b-D-maltoside and Novek.

In one example, the nanowire dispersion may include, by weight, from 0.0025% to 0.1% surfactant (e.g., a preferred range is from 0.0025% to 0.05% for Zonyl® FSO-100), from 0.02% to 4% viscosity modifier (e.g., a preferred range is 0.02% to 0.5% for HPMC), from 94.5% to 99.0% solvent and from 0.01% to 1.4% nanowires 18.

The carrier fluid may further include solvents that may help adjust the curing rate and viscosity of the solution in its liquid state. The solvents evaporate off as the solution dries. There are two types of carrier solutions: solvent-based and water-based. Examples of suitable solvents include alcohols, ketones, ethers, hydrocarbons or aromatic solvents (benzene, toluene, xylene, etc.) as mentioned above. The ratios of components of the dispersion may be modified depending on the substrate and the method of application used. The viscosity range of the GMR nanowire carrier liquid may vary greatly depending on the method of application. For inkjet printing applications, the viscosity can range from about 1 to about 40 cP; for gravure printing about 40 to about 200 cP; and for screen printing, over 1000 cP. Thus, the viscosity may generally range from about 0.3 to about 2000 cP (or any subrange in between). One preferred viscosity range for the nanowire dispersion is between about 1 and 40 cP (or any subrange there between). Certain embodiments of the carrier fluid may include flux concentrator agents such as nanoparticles from an alloy consisting of cobalt, magnetite, or iron.

After the carrier fluid containing the nanowires 18 has been applied to the substrate 12, the carrier fluid (or certain components thereof) may be evaporated, leaving the nanowires 18 distributed on the surface of the substrate 12 and extending between the terminals 14, 16 as shown in FIGS. 1a and 1b. The nanowires 18 may thereby provide an electrically conductive pathway between the terminals 14, 16.

The MR sensor 10 may further include an oxygen barrier composition 20 (hereinafter “the composition 20”) that is applied over, and that covers, coats, and envelopes, the nanowires 18. The composition 20 may seal the nanowires 18 from a surrounding environment and may prevent oxygen and moisture from coming into contact with the nanowires 18, thereby protecting the nanowires 18 from galvanic corrosion. The composition 20 and methods for applying the composition 20 to the substrate 12 and nanowires 18 will now be described in detail.

As used herein, an “A-stage” or “A-staged” physical state of the composition 20 is characterized by a linear structure, solubility, and fusibility. In certain embodiments, the A-staged composition 20 may be a high viscosity liquid, having a defined molecular weight, and comprised of largely unreacted compounds. In this state, the composition 20 will have a maximum flow (in comparison to a B-staged or C-staged material). In certain embodiments, the A-staged composition 20 may be changed from an A-staged state to either a B-staged state or a C-staged state via either a photo-initiated reaction or thermal reaction.

As used herein, a “B-stage” or “B-staged” physical state of the composition 20 is achieved by partially curing the A-stage composition 20, wherein at least a portion of the A-stage composition 20 is crosslinked, and the molecular weight of the material increases. Unless indicated otherwise, the B-stage state can be achieved through either a thermal latent cure or a UV-cure. In certain embodiments, the B-staged composition 20 is achieved through a thermal latent cure. B-staged reactions can be arrested while the product is still fusible and soluble, although having a higher softening point and melt viscosity than before. The B-staged composition 20 contains sufficient curing agent to effect crosslinking on subsequent heating. In certain embodiments, the B-stage composition 20 is fluid, or semi-solid, and, therefore, under certain conditions, can experience flow. In the semi-solid form, the thermosetting polymer may be handled for further processing by, for example, and operator. In certain embodiments, the B-stage composition 20 comprises a conformal tack-free film, workable and not completely rigid, allowing the composition 20 to be molded or flowed around an electrical device.

As used herein, a “C-stage” or “C-staged” physical state of the composition 20 is achieved by fully curing the composition 20. In some embodiments, the C-staged composition 20 is fully cured from an A-staged state. In other embodiments, the C-staged composition 20 is fully cured from a B-staged state. Typically, in the C-stage, the composition 20 will no longer exhibit flow under reasonable conditions. In this state, the composition 20 may be solid and, in general, may not be reformed into a different shape.

The composition 20 may include meta-substituted aromatic resins. In certain embodiments, the meta-substituted aromatic resins are selected from the group consisting of: meta-substituted resorcinol epoxy resins, meta-substituted acrylic resorcinol resins, meta-substituted methacrylic-resorcinol resins, meta-substituted xylenediamine resins, resorcinol, and combinations thereof. In one embodiment, the meta-substituted aromatic resin is a meta-substituted resorcinol epoxy resin. In another embodiment, the meta-substituted aromatic resin is a meta-substituted acrylic resorcinol resin, meta-substituted methacrylic-resorcinol resin, or combination thereof. In still another embodiment, the meta-substituted aromatic resin is a tetraglycidyl xylenediamine resin.

In certain embodiments, meta-substituted resorcinol resins in the composition 20 have the general structure (I):

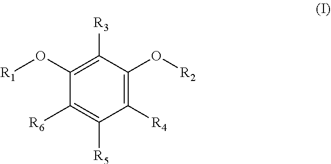

wherein the general structure includes oligomers thereof.

In some embodiments, R₁ and R₂, including or joined to the —O— linking group, each independently form a curable functionality selected from the group consisting of glycidyl (such as glycidyl ether), aliphatic epoxy, acrylic (such as acrylate), methacrylic (such as methacrylate), itaconate, cycloaliphatic epoxy, hydroxyl, vinyl ether, propenyl ether, crotyl ether, styrenic, maleimide, maleate, fumarate, cinnamate, acrylamide, methacrylamide, chalcone, thiol, allyl, alkynyl, alkenyl, and cycloalkenyl groups. In certain embodiments, R₁ and R₂ are the same.

In certain embodiments, R₃, R₄, R₅, and R₆ are independently selected from the group consisting of: hydrogen, alkyl, vinyl, acrylic, methacrylic, aryl, substituted alkyl, substituted aryl, halogen, and cyano groups. In other embodiments, in addition to the groups discussed above, R₃, R₄, R₅, and R₆ may also be independently selected from the groups discussed for R₁ and R₂.

In one embodiment, the meta-substituted resorcinol epoxy resin is a resorcinol diglycidyl ether resin having the general structure (II) below:

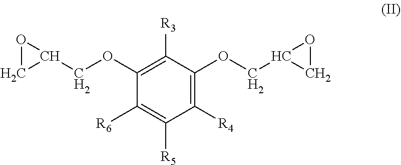

In one embodiment, the meta-substituted resorcinol epoxy resin is resorcinol diglycidyl ether (RDGE) (where R₃, R₄, R₅, and Rₕ in (II) are hydrogen). RDGE has good oxygen barrier properties, as well as good chemical resistance, flexibility, and adhesion to a variety of substrates. RDGE also features low viscosity (approximately 200-500 cps at 25° C.), which allows for flexibility in the oxygen barrier composition 20 formulation, such as the addition of highly viscous epoxy components, fillers, or thixotropes. RDGE-based resins may provide advantageous conformer packing, improved hydrogen bonding, and inter/intra-chain interaction within the resin in comparison to other epoxy resins.

In a particular embodiment, the RDGE resin is ERISYS™ RDGE-H, a purified form of RDGE, available from CVC Thermoset Specialties Division of Emerald Performance Materials, Cuyahoga Falls, Ohio, USA. RDGE-H has a viscosity of about 200-325 cps at 25° C. and approximately 2300-2500 ppm chlorine.

In additional embodiments, the RDGE resin may have substitutions for hydrogen at the R₃, R₄, R₅, and/or R₆ positions, as well as at any hydrogen position on either glycidyl ether.

In additional embodiments, the RDGE resin may be oligomerized, as shown in the structure (III) below:

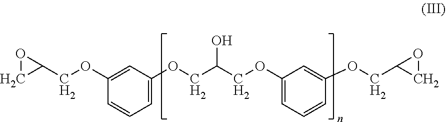

wherein n=1, 2, 3, or greater. As n increases, the viscosity of the composition 20 increases as well. In certain embodiments, a higher, more viscous oligomer or adduct may be used for a high viscosity application, such as a pre-preg preparation. In certain embodiments, a workable composition 20 has a viscosity between approximately 200 and approximately 50,000 cps; between approximately 200 cps and approximately 10,000 cps; or between approximately 200 cps and approximately 1000 cps. In certain embodiments, the value of n should not be so large that the viscosity is above approximately 50,000 cps; approximately 10,000 cps; or approximately 1000 cps.

Additionally, in another embodiment, the meta-substituted aromatic resin is a meta-substituted acrylic resorcinol resin, meta-substituted methacrylic-resorcinol resin, or combination thereof, including oligomers or adducts thereof, such as the resorcinol epoxy acrylate structure (IV) shown below:

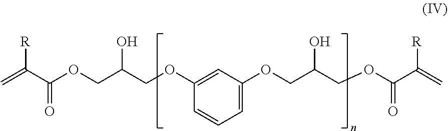

wherein n=0, 1, 2, 3, or greater. As n increases, the viscosity of the composition 20 increases as well. In certain embodiments, a workable composition 20 has a viscosity between approximately 200 and approximately 50,000 cps; between approximately 200 cps and approximately 10,000 cps; or between approximately 200 cps and approximately 1000 cps. In certain embodiments, the value of n should not be so large that the viscosity is above approximately 50,000 cps; approximately 10,000 cps; or approximately 1000 cps.

In one embodiment, the meta-substituted acrylic resorcinol resin, meta-substituted methacrylic-resorcinol resin, or combination thereof comprises a resorcinol-type epoxyacrylate such as NEOPOL 8312 or NEOPOL 8313, supplied by Japan U-PiCA Co., Tokyo, Japan.

In some embodiments, the meta-substituted aromatic resin is tetraglycidyl xylenediamine, including oligomers or adducts thereof, having the structure shown below:

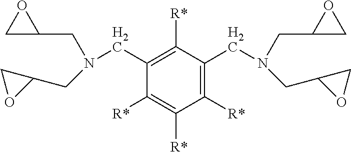

wherein R″ may independently comprise any substitution. In one embodiment, each R″ is hydrogen, and the tetraglycidyl xylenediamine resin is N,N,N′,N′-tetraglycidyl-m-xylenediamine. Commercial examples are available as TETRAD-X from Mitsubishi Gas Chemical Co., Tokyo, Japan or ERISYS™ GA-240 from CVC Thermoset Specialties Division of Emerald Performance Materials, Cuyahoga Falls, Ohio, USA.

In certain embodiments, the amount of the meta-substituted aromatic resin in the composition 20 can range between approximately 1% by weight and approximately 100% by weight, between approximately 5% by weight and approximately 50% by weight, between approximately 10% by weight and approximately 40% by weight, or between approximately 20% by weight and 30% by weight, wherein “% by weight” is defined in terms of the total resin weight in the composition 20, unless noted otherwise. In still another embodiment, the amount of meta-substituted aromatic resin is approximately 25% by weight of the total weight of resin present in the composition 20.

In some embodiments, the properties of the composition 20 are adjusted, such as by reducing the halogen content (e.g., the chlorine content), increasing the viscosity, or increasing the glass transition temperature (T_{g}) of the composition 20 by adding additional component(s) to the composition 20. In one embodiment, an aromatic epoxy resin is added to the meta-substituted aromatic resin-containing barrier composition 20. In one embodiment, the aromatic epoxy resin is selected from the group consisting of: bisphenol-F diglycidyl ether, N,N,N′,N′-tetraglycidyl-m-xylenediamine (such as TETRAD-X from Mitsubishi Gas Chemical Co. or ERISYS™ GA-240 from CVC Thermoset Specialties Division of Emerald Performance Materials), bisphenol-A diglycidyl ether, epoxidized phenol novolac resins, epoxidized cresol novolac resins, polycyclic epoxy resins, naphthalene diepoxides, and combinations thereof. In certain embodiments, the aromatic epoxy resin has a low chlorine content of less than approximately 900 ppm. In one embodiment, the aromatic epoxy resin comprises bisphenol-F diglycidyl ether, which has strong oxygen barrier properties and low chlorine content. JER Y983U, a bisphenol-F having approximately 300 ppm Cl, is available from Japan Epoxy Resins Co., Tokyo, Japan.

In another embodiment, the aromatic epoxy resin is a naphthalene diglycidyl ether which complements the meta-substituted aromatic resin, offering high chemical resistance, high glass transition temperature, and good oxygen barrier properties. One source of a naphthalene diglycidyl ether is EPICLON® HP-4032D, containing approximately 900 ppm chlorine, from DIC Japan, Tokyo, Japan.

In certain embodiments, the addition of the aromatic epoxy resin reduces the chlorine and/or overall halogen content in the composition 20, assisting in the reduction of toxic halogenated by-products, such as dioxin and furans, upon disposal or recycling by incineration or burning of electronic components. In some embodiments, the addition of the aromatic epoxy resin reduces the chlorine content to less than approximately 2000 ppm, less than approximately 1500 ppm, less than approximately 1000 ppm, or less than approximately 900 ppm. In some embodiments, the addition of the aromatic epoxy resin to the meta-substituted aromatic resin results in an overall halogen content of less than approximately 2000 ppm, less than approximately 1500 ppm, less than approximately 1000 ppm, or less than approximately 900 ppm. In one embodiment, the chlorine content is reduced below approximately 1000 ppm and the overall halogen content is reduced below approximately 2000 ppm. In another embodiment, the chlorine content is reduced below approximately 900 ppm and the overall halogen content is reduced below approximately 1500 ppm. In one embodiment, the combination of RDGE and the aromatic epoxy resin results in a reduced chlorine level of less than approximately 900 ppm with substantially no bromine detected (e.g., less than 10 ppm bromine).

In certain embodiments, the addition of the aromatic epoxy resin increases the glass transition temperature (T_{g}) upwards of approximately 150° C. In other embodiments, the addition increases T_{g} to approximately 160° C. or greater. In other embodiments, the addition increases T_{g} by approximately 10° C. to approximately 60° C. Considerations of the glass transition temperature for the composition 20 are important for PPTC devices in particular. PPTC devices can expand upwards of 10% during use. As the device warms during use, it reaches a certain “trip temperature” at which the device begins expanding. To allow for expansion, it is generally recommended that T_{g} for the composition 20 encapsulating or covering the PPTC device be equal to or less than the trip temperature of the device, allowing the device to expand more readily due to the barrier composition 20 being in a more rubbery state at the trip temperature. Desirable compositions also maintain their barrier properties in this rubbery state. The inventors have discovered that these compositions can maintain their properties.

The amount of aromatic epoxy resin added to the composition 20 can be varied based upon the oxygen barrier properties desired, such as oxygen permeability, halogen content, and viscosity. In certain embodiments, the amount of aromatic epoxy resin in the composition 20 ranges between 0% by weight and approximately 99% by weight of the total resin weight in the composition 20. In other embodiments, the amount is between approximately 1% by weight and approximately 80% by weight of the total resin weight. In other embodiments, the amount is between approximately 1% by weight and approximately 25% by weight of the total resin weight. In one embodiment, the amount of aromatic epoxy resin in the composition 20 is approximately 75% by weight of the total resin weight.

In other embodiments, the ratio of meta-substituted aromatic resin (e.g., RDGE) to the aromatic epoxy resin (e.g., a bisphenol-F epoxy resin) is between approximately 1:10 and approximately 10:1. In other embodiments, the ratio is between approximately 1:5 and approximately 5:1. In other embodiments, the ratio is between approximately 1:2 and approximately 2:1. In other embodiments, the ratio of meta-substituted aromatic resin (e.g., RDGE) and the aromatic epoxy resin (e.g., bisphenol-F) is approximately 1:1.

In addition to adding an aromatic epoxy resin to the meta-substituted aromatic resin, or in the alternative of adding an aromatic epoxy resin, the composition 20 can include a variety of fillers, such as platelet-type fillers, reinforcing-type fillers (such as glass fibers or other structural components), alumina-type fillers, and silica-type fillers, boron nitride, or other suitable filler. These fillers may be used to adjust the composition 20 properties, such as decreasing halogen levels (e.g., chlorine levels), increasing viscosity, decreasing shrinkage in the cured resin, or increasing the barrier properties by presenting a tortuous path. In some embodiments, a silica filler can be added to the composition 20, in part to help reduce the overall chlorine or overall halogen content without an appreciable increase in viscosity. One example of a silica filler is FB-5D fused silica filler available from Denka, Tokyo, Japan. In another embodiment, a filler may increase viscosity for easier application and less running. A silica filler of this type is CAB-O-SIL TS-720, available from Cabot Corp., Boston, Mass., USA.

In certain embodiments, the filler comprises a platelet-type filler, such as platelet silicas (such as ground mica), flaked glass, chemically modified silacious minerals such as organoclays, or combinations thereof. In one embodiment, the platelet-type filler is an organoclay filler.

Like the amount of aromatic epoxy resin added to the composition 20, the amount of filler can be varied based upon the oxygen barrier properties desired, such as oxygen permeability, chlorine content, viscosity, reduced epoxy usage (i.e., cost of manufacturing). Because these fillers have substantially no halogen/chlorine content, the weight percent of filler added can correlate directly with reduction in chlorine ppm levels. For example, adding approximately 25% by weight filler to the composition 20 may reduce the overall chlorine content by approximately 25% (wherein the percent by weight filler in the composition 20 is defined in terms of the combined weight of resin and filler, excluding any curing agent or accelerant in the composition 20). In addition, the filler may increase the overall viscosity of the composition 20. For example, the addition of a small amount (approximately 2% by weight) of CAB-O-SIL TS-720 to a RDGE/aromatic epoxy composition 20 can increase the overall viscosity 10-fold (e.g., from about 1000 cps to about 10,000 cps). Therefore, the amount of filler added may be varied based upon the desired composition 20 properties. In certain embodiments, the amount of filler is between approximately 0.1% by weight and approximately 80% by weight filler/combined resin and filler. In other embodiments, the amount is between approximately 1% by weight and approximately 50% by weight filler/combined resin and filler. In other embodiments, the amount is between approximately 20% by weight and approximately 80% by weight filler/combined resin and filler.

In addition to aromatic epoxy resins and/or fillers, a particular curing agent (i.e., initiator) can be added to the composition 20 to improve the oxygen barrier properties and the ease of cure. As discussed in greater detail below, the addition of a particular curing agent to the barrier composition 20 can be helpful for: (i) thermal latent curing for encapsulation and/or pre-preg manufacture (i.e., “B-stage” curing), (ii) complete curing in one step, and/or (iii) complete curing at the solder reflow step. In certain embodiments, the curing agent is an amine curing agent. Amine curing agents may assist in providing good oxygen barrier properties to a resin composition in multiple ways. For example, it is believed that the polarity and hydrogen bonding ability of the nitrogen molecules provides denser packing by inter/intra chain interactions. Additionally, amine curing agents that possess multiple active hydrogen atoms on the nitrogen atom may produce branched and cross-linked structures that are denser, and therefore may provide improved oxygen blocking ability. Another notable feature among some amine curing agents is that they exhibit multiple thermal decomposition pathways that may yield dense and crosslinked structures that are improved over curing agents that form more linear ethereal chain structures during and after cure. Finally, amines have the ability to capture wet carbon dioxide and convert it to bicarbonate, further filling gaps in the composition 20 matrix and thus slowing down oxygen ingress.

In one embodiment, the amine curing agent is an aromatic amine curing agent. Aromatic amine curing agents comprise compounds that have a nitrogen group directly attached to an aromatic group, such as the non-limiting example of a meta-substituted aromatic amine shown below in structure (V):

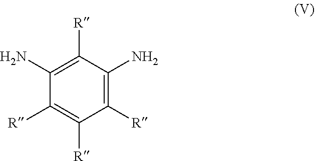

wherein each R″ may independently comprise any substitution (such as hydrogen, alkyl groups, and other suitable groups). Ortho- and para-substituted aromatic amines are also possible. In certain embodiments, meta-substituted aromatic amines are chosen for their oxygen barrier properties.

In an additional embodiment, the amine curing agent comprises an aromatic-substituted amine curing agent, wherein that the compound has a nitrogen group linked through a connector (such as an alkyl group) to the aromatic group, wherein the connector can be approximately 20 atom spacers (R′ below) or less (such as CH₂, O, N, and other suitable spacers). A non-limiting example of an aromatic-substituted amine curing agent is shown below in structure (VI):

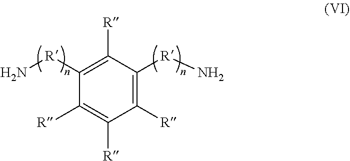

wherein both R′ groups independently function as at least one spacer atom between the aromatic substituent and nitrogen, each R″ may independently comprise any substitution (such as hydrogen, alkyl groups, etc.), and n is any integer of 1 or greater. Ortho- and para-substituted amines are also possible. In certain embodiments, meta-substituted amines are used. In some embodiments, n is an integer between 1 and 20. In one embodiment, an aromatic-substituted amine curing agent is meta-xylenediamine.

In one particular embodiment, the aromatic amine curing agent is a diaminodiphenyl sulfone. One commercial example is OMICURE™ 33DDS, a 3,3′-diaminodiphenyl sulfone, available from CVC Thermoset Specialties Division of Emerald Performance Materials, Cuyahoga Falls, Ohio, USA.

In one embodiment, the aromatic amine is a meta-substituted aromatic amine such as meta-phenylenediamine, 3,3′-diaminodiphenyl sulfone, 4,4′-diaminodiphenyl sulphone, melamine, and the like, and combinations thereof.

In certain embodiments, the amount of aromatic amine curing agent included in the composition 20 is based upon the amount of resorcinol epoxy resins and other aromatic epoxy resins present in the composition 20, as the active hydrogens present in the aromatic amines will react with a stoichiometric number of epoxy groups. In some embodiments, the amount of aromatic amine curing agent is within a 10% or 20% stoichiometric amount of the resorcinol/aromatic epoxy resins.

In other embodiments, the curing agent is an anhydride curing agent. In one particular embodiment, the anhydride curing agent is an aromatic anhydride curing agent. An example of an anhydride curing agent is phthalic anhydride.

In certain embodiments, the curing agent is a thermal curing agent capable of either (i) a one-time, full cure (i.e., A-stage to C-stage cure), (ii) a B-stage cure, and/or (iii) a complete cure of a B-stage composition 20 at the solder reflow step. In certain embodiments, the curing agent is selected from dicyandiamide (DICY), dihydrazide compounds, aromatic amines, boron trifluoride-amine complex, and combinations thereof. In one embodiment, the curing agent comprises DICY. One commercial example of DICY is OMICURE® DDA 5, available from CVC Thermoset Specialties Division of Emerald Performance Materials, Cuyahoga Falls, Ohio, USA.

In certain embodiments, the curing agent may be a visible light-curing agent or ultraviolet-curing agent. In these embodiments, the purpose of the curing agent is to initiate polymerization of the meta-substituted aromatic resin when exposed to light- or UV-radiation. In certain embodiments, the light-curing agent or UV-curing agent is coupled with a meta-substituted acrylic resorcinol resin, meta-substituted methacrylic-resorcinol resin, or combination thereof. In some embodiments, the light- or ultraviolet-curing agent is a free-radical photoinitiator. Free-radical photoinitiators useful for meta-substituted acrylic resorcinol resins and meta-substituted methacrylic-resorcinol resins (such as resorcinol epoxy acrylate or resorcinol epoxy methacrylate) include, but are not limited to, photofragmentation photoinitiators and electron transfer photoinitiators. Non-limiting examples include: alkyl ethers of benzoin, benzyl dimethyl ketal, 2-hydroxy-2-methylphenol-1-propanone, diethoxyacetophenone, 2-benzyl-2-N, N-dimethylamino-1-(4-morpholinophenyl) butanone, halogenated acetophenone derivatives, sulfonyl chlorides of aromatic compounds, acylphosphine oxides and bis-acyl phosphine oxides, benzimidazoles, benzophenone, diphenoxy benzophenone, halogenated and amino functional benzophenones, Michler's ketone, fluorenone derivatives, anthraquinone derivatives, zanthone derivatives, thioxanthone derivatives, camphorquinone, benzil, dimethyl ethanolamine, thioxanthen-9-one derivatives, acetophenone quinone, methyl ethyl ketone, valero-phenone, hexanophenone, gamma-phenylbutyrophenone, p-morpholinopropiophenone, dibenzosuberone, 4-morpholinobenzophenone, 4-morpholinodeoxybenzoin, p-diacetylbenzene, 4-aminobenzophenone, benzaldehyde, alpha-tetraline, 9-acetylphenanthrene, 2-acetylphenanthrene, 10-thioxanthenone, 3-acetylphenanthrene, 3-acetylindole, 9-fluorenone, 1-indanone, 1,3,5-triacetylbenzene, thioxanthen-9-one, xanthene-9-one, 7-H-benz[de]-anthracen-7-one, 1-naphthaldehyde, 4,5′-bis(dimethylamino)-benzophenone, fluorene-9-one, 1′-acetonaphthone, 2′-acetonaphthone, 2,3-butanedione, and combinations thereof. Commercial examples include: Ciba IRGACURE® 651, a benzyldimethyl-ketal, from Ciba, Tarrytown, N.Y., USA; Additol BCPK, a benzophenone phenyl ketone eutectic, from Cytec Industries, West Paterson, N.J., USA; and Ciba IRGACURE®, a phosphine oxide, from Ciba, Tarrytown, N.Y., USA.

Regarding the amount of curing agent that may be added to the composition 20, the amount added is generally described in parts of curing agent per hundred parts of total resin present in the composition 20 (“phr”). In certain embodiments, the amount is between approximately 0.1 phr and approximately 40 phr (i.e., 40 grams curing agent per 100 grams total resin); approximately 0.1 phr and approximately 5 phr; or approximately 10 phr and approximately 40 phr. In one embodiment, the amount of curing agent is approximately 5 phr (i.e., 5 grams curing agent per 100 grams total resin).

In certain embodiments, where the curing agent is a light- or UV-curing agent, the amount of curing agent added is between approximately 0.1 phr and approximately 5 phr.

In certain embodiments, an accelerant may be added to speed up the curing process or reduce the temperature for the thermal latent cure or one-time cure. In certain embodiments, the accelerant is added in combination with a curing agent. In certain embodiments, the amount of accelerant is between approximately 0.1 phr and approximately 40 phr; between approximately 0.1 and approximately 5 phr; or between approximately 10 phr and approximately 40 phr. In one embodiment, the amount of accelerant is approximately 5 phr.

Various thermal curing accelerants are known in the art, including phenyl ureas, boron trichloride amine complexes, imidazoles, aliphatic bis ureas, phenols, resorcinol, and combinations thereof. In one embodiment, an effective accelerant for the composition 20 is a phenyl urea, where the phenyl urea has a nitrogen content that may further assist in providing good oxygen barrier properties via denser packing and inter/intra chain interaction. Non-limiting examples of phenyl urea accelerants include: phenyl dimethyl urea, 4,4′ methylene bis(phenyl dimethyl urea), 2,4′ toluene bis(dimethyl urea), and combinations thereof. A commercial example of phenyl dimethyl urea is OMICURE™ U-405 or U-405M, available from Thermoset Specialties Division of Emerald Performance Materials, Cuyahoga Falls, Ohio, USA. A commercial example of 4,4′ methylene bis(phenyl dimethyl urea) is OMICURE™ U-52 or U-52M. A commercial example of 2,4′ toluene is OMICURE™ U-24 or U-24M. In another embodiment, the accelerant is a boron trichloride amine complex, available as OMICURE™ BC-120. In another embodiment, the accelerant is 2-ethyl-4-methyl imidazole, available as OMICURE™ 24 EMI. In another embodiment, the accelerant is an aliphatic bis urea, available as OMICURE™ U-35 or U-35M.

In another embodiment, a meta-substituted phenol can be used as an accelerator when coupled with an aromatic epoxy resin and DICY. In one embodiment, the phenol is resorcinol. In another embodiment, the phenol is phloroglucinol. The use of a meta-substituted phenol, such as resorcinol, as the accelerator may be advantageous as it introduces an additional meta-substituted aromatic resin into the resin matrix and may further enhance the oxygen barrier properties.

In one embodiment, the combination of DICY and a phenyl urea accelerant provides high amine content for polarity and enhanced barrier properties as well as multi-functional sites for crosslinking and branching. In one embodiment, DICY is combined with a phenyl dimethyl urea. In one embodiment, DICY is combined with a 4′4 methylene bis(phenyl dimethyl urea). In another embodiment, DICY is combined with a 2,4′ toluene bis(dimethyl urea). In another embodiment, DICY is combined with an aliphatic bis urea (OMICURE™ U-35 or U-35M in particular).

In one embodiment, the composition 20 comprises a meta-substituted aromatic resin (e.g., RDGE) ranging between approximately 1% by weight and approximately 100% by weight of the composition 20 and optionally, at least one of: (i) an aromatic epoxy resin (e.g., bisphenol-F) ranging between approximately 0.1% by weight and approximately 99% by weight; (ii) a filler (e.g., an alumina, silica, or platelet-like filler) ranging between approximately 0.1% by weight and approximately 80% by weight; (iii) a curing agent (e.g., DICY or an aromatic amine curing agent) ranging between approximately 0.1 phr and approximately 40 phr; and (iv) an accelerant (e.g., a phenyl urea) used jointly with the curing agent, and ranging between approximately 0.1 phr and approximately 40 phr.

In another embodiment, the composition 20 comprises a resorcinol-based resin (e.g., RDGE) ranging between approximately 10% by weight and approximately 40% by weight of the total weight of resin; an aromatic epoxy resin (e.g., bisphenol-F) ranging between approximately 10% by weight and approximately 80% by weight of the total weight of resin; a filler (e.g., an alumina, silica, or platelet-like filler) ranging between approximately 0% by weight and approximately 80% by weight filler/combined resin and filler; an amine curing agent (e.g., DICY) ranging between approximately 0.1 phr and approximately 40 phr; and an accelerant (e.g., a phenyl urea) used jointly with the curing agent, and ranging between approximately 0.1 phr and approximately 40 phr.

In one embodiment, the composition 20 comprises approximately 25% by weight of total resin weight RDGE, approximately 75% by weight of total resin weight bisphenol-F aromatic epoxy resin, approximately 5 phr DICY as the amine curing agent, and approximately 5 phr phenyl urea accelerant.

Various physical or performance-based properties may be targeted with the composition 20, prompting the choice of using certain components in certain amounts. For example, the composition 20 may have a targeted chlorine or overall halogen content, low viscosity, high oxygen barrier, certain solids content (i.e., limited amounts of solvents or VOCs), excellent chemical resistance, flexibility in working the barrier coating around an electronic device, and excellent adhesion to a variety of substrates.

In certain embodiments, the composition 20 has a chlorine content below approximately 2000 ppm; approximately 1500 ppm; approximately 1000 ppm; or approximately 900 ppm. In another embodiment, the composition 20 has a chlorine content below approximately 1500 ppm. In some embodiments, the composition 20 has an overall halogen content (bromine and chlorine combined) below approximately 2000 ppm; approximately 1500 ppm; approximately 1000 ppm; or approximately 900 ppm.

In certain embodiments, low viscosity for ease in application is a desirable property. In one embodiment, the viscosity of the composition 20 is between approximately 200 and approximately 50,000 cps. In another embodiment, the viscosity is between approximately 200 and approximately 10,000 cps. In another embodiment, the viscosity is between approximately 200 and approximately 1000 cps.

In certain embodiments, the composition 20 may have targeted high barrier properties for oxygen. In one embodiment, the oxygen permeability of the composition 20 is less than approximately 0.4 cm³·mm/m²·atm·day (1 cm³·mil/100 in²·atm·day), measured as cubic centimeters of oxygen permeating through a sample having a thickness of one millimeter over an area of one square meter. The permeation rate is measured over a 24 hour period, at 0% relative humidity, and a temperature of 23° C. under a partial pressure differential of one atmosphere). Oxygen permeability may be measured using ASTM F-1927 with equipment supplied by Mocon, Inc., Minneapolis, Minn., USA. Unless defined otherwise, the oxygen permeability is based on a measurement at approximately 0% relative humidity.

In some embodiments, the oxygen permeability of the composition 20 is less than approximately 0.3 cm³·mm/m²·atm day; approximately 0.2 cm³·mm/m²·atm·day; approximately 0.1 cm³·mm/m²·atm·day; approximately 0.05 cm³·mm/m²·atm·day; or approximately 0.01 cm³·mm/m²·atm·day.

In certain embodiments, the composition 20 has a solids content of greater than approximately 90% by weight of the total composition 20. In other embodiments, the solids content is greater than approximately 95% by weight of the composition 20. In other embodiments, the composition 20 is substantially solvent-free (i.e., less than approximately 1% by weight solvent in the total composition 20, or near 100% by weight solids in the total composition 20), having substantially no volatile organic compounds (i.e., having less than 1% by weight VOCs in the total composition 20).

The composition 20 gel time may also be a parameter of interest. The gel time is the time it takes from the beginning of mixing the components at a certain temperature (e.g., 171° C.) until the point at which the composition 20 turns from a viscous liquid to an elastomer having memory. In certain embodiments, the gel time for the composition 20 is between approximately 150 seconds and approximately 250 seconds when mixed at approximately 171° C.

The various embodiments described herein may be used for a variety of electrical or other devices. In certain embodiments, the composition 20 is used in a circuit protection device, such as an over-current device or over-voltage device. In a particular embodiment, the composition 20 is used in a PPTC device, such as those defined in U.S. Pat. No. 7,371,459, herein incorporated by reference. Various PPTC devices include surface mount devices (SMDs) and battery strap devices. In certain embodiments, the oxygen barrier may encapsulate various SMDs, such as those described in U.S. patent application Ser. No. 12/460,349, filed Jul. 17, 2009, entitled “Oxygen-Barrier Packaged Surface Mount Device,” now U.S. Pat. No. 8,525,635, herein incorporated by reference. Based upon the particular electronic device being used, in certain embodiments, the thickness of the composition 20 may range between approximately 0.05-0.65 mm (2-25 mils).

The composition 20 may be applied to the electrical device in a variety of forms. In one embodiment, the composition 20 can be applied as a coating or encapsulant to the electrical device. In particular, the composition 20 can encapsulate a SMD or battery strap device.

In another embodiment, the composition 20 can be applied to electrical device through B-stageable “pre-preg” sheets. For instance, the composition 20 can be applied to a fiberglass cloth (typically by soaking the cloth in the composition 20 resin), followed by partially curing the fiberglass and composition 20 to a B-stage. The partially cured resin remains workable and not completely rigid, allowing the pre-preg to be molded or flowed around the electrical device, at which point the device can be fully cured (i.e., C-stage cure). In one embodiment, an electrical device (e.g., a PPTC device) can be laminated between the pre-preg sheets.

In another embodiment, the composition 20 can be applied to an electrical device as a partially cured, B-stage powder, pellet, tape, film, or pre-preg sheet. In some embodiments, the composition 20 is applied as a powder coating, transfer molding, or sheet lamination. In one embodiment, the B-stage composition 20 may be coated onto a backing of a substrate, such as an electrical device. In another embodiment, the B-stage composition 20 can be electrostatically sprayed onto a substrate, e.g., electrical device. This may be a useful method of application for electrical devices such as R-line, telecom, or semiconductor packaging.

In certain embodiments, the composition 20 may have improved pot-life (shelf-life) at approximately 23° C. (i.e., room temperature) in comparison to known, two-part epoxy formulations, where the pot-life is approximately 6-24 hours at 23° C. In some embodiments, the pot-life of the composition 20 is at least approximately 3 months or at least approximately 6 months at approximately 23° C. In some embodiments, the pot-life of the composition 20 containing DICY as a curing agent is at least approximately 3 months or at least approximately 6 months at approximately 23° C. In another embodiment, the pot-life of the composition 20 containing DICY as a curing agent is between approximately 3 months and approximately 6 months at approximately 23° C. In some embodiments, the pot-life of the composition 20 is indefinite at 0° C.

The composition 20 may be cured through a number of different methods. In one embodiment, the composition 20 is fully cured (i.e., C-stage cured) in a single thermal stage. The operating temperature for fully curing the composition 20 may vary based upon certain variables including the constituents of the composition 20 (i.e., if there is an accelerator or not) and the time held at the elevated temperature. In certain embodiments, with or without an accelerator, a one-time full cure can be accomplished at a temperature of between approximately 150° C. and approximately 260° C. for about 1-6 hours.

In another embodiment, the composition 20 can be partially-cured through a thermal latent, B-stage cure. As mentioned above, this partial cure method is useful for pre-pregs among other embodiments. The partially cured resin allows the composition 20 to form a conformal tack-free film, workable and not completely rigid, allowing the barrier composition 20 to be molded or flowed onto the nanowires 18 and substrate 12. Operating temperatures for B-stage curing may vary based upon certain variables including the constituents of the composition 20 (i.e., if there is an accelerator or not) and the time held at the elevated temperature. In certain embodiments, with or without an accelerator, the temperature of the partial cure can range between approximately 25° C. and approximately 150° C. for a time between approximately 5 minutes to several hours (e.g., between approximately 2-24 hours).

In certain embodiments, after partially curing the composition 20 and applying the B-stage composition 20 to the nanowires 18 and substrate 12, the composition 20 may be fully cured. In certain embodiments, the final cure can occur at elevated temperatures between approximately 125° C. and approximately 170° C. In another embodiment, the final cure of the B-stage composition 20 is effectuated through a solder reflow step, wherein the composition 20 and the MR sensor 10 are heated to approximately 260° C. to solder the terminals 14, 16 to other electrical components (e.g., contacts on a printed circuit board). Thus, the soldering step accomplishes two goals at the same time, wherein both the barrier composition 20 is fully cured and the terminals 14, 16 are soldered to another component at the same time.

In another curing embodiment, a composition 20 comprising a meta-substituted acrylic resorcinol resin, meta-substituted methacrylic-resorcinol resin, or combination thereof is curable by ultraviolet light. The UV cure may be accomplished with free-radical photoinitiators. The inventors have discovered that a free-radical cure may produce polymers with an improved oxygen barrier with stronger crosslinking and higher density over a cationic cure which may polymerize to form polyether structures with poor oxygen barrier properties.

Free-radical photoinitiators useful for meta-substituted acrylic resorcinol resins or meta-substituted methacrylic-resorcinol resins (such as resorcinol epoxy acrylate or resorcinol epoxy methacrylate) include, but are not limited to, photofragmentation photoinitiators and electron transfer photoinitiators. Non-limiting examples include: alkyl ethers of benzoin, benzyl dimethyl ketal, 2-hydroxy-2-methylphenol-1-propanone, diethoxyacetophenone, 2-benzyl-2-N, N-dimethylamino-1-(4-morpholinophenyl) butanone, halogenated acetophenone derivatives, sulfonyl chlorides of aromatic compounds, acylphosphine oxides and bis-acyl phosphine oxides, benzimidazoles, benzophenone, diphenoxy benzophenone, halogenated and amino functional benzophenones, Michler's ketone, fluorenone derivatives, anthraquinone derivatives, zanthone derivatives, thioxanthone derivatives, camphorquinone, benzil, dimethyl ethanolamine, thioxanthen-9-one derivatives, acetophenone quinone, methyl ethyl ketone, valero-phenone, hexanophenone, gamma-phenylbutyrophenone, p-morpholinopropiophenone, dibenzosuberone, 4-morpholinobenzophenone, 4-morpholinodeoxybenzoin, p-diacetylbenzene, 4-aminobenzophenone, benzaldehyde, alpha-tetraline, 9-acetylphenanthrene, 2-acetylphenanthrene, 10-thioxanthenone, 3-acetylphenanthrene, 3-acetylindole, 9-fluorenone, 1-indanone, 1,3,5-triacetylbenzene, thioxanthen-9-one, xanthene-9-one, 7-H-benz[de]-anthracen-7-one, 1-naphthaldehyde, 4,5′-bis(dimethylamino)-benzophenone, fluorene-9-one, 1 ‘-acetonaphthone, 2’-acetonaphthone, 2,3-butanedione, and combinations thereof. Commercial examples include: Ciba IRGACURE® 651, a benzyldimethyl-ketal, from Ciba, Tarrytown, N.Y., USA; Additol BCPK, a benzophenone phenyl ketone eutectic, from Cytec Industries, West Paterson, N.J., USA; and Ciba IRGACURE®, a phosphine oxide, from Ciba, Tarrytown, N.Y., USA.

In an additional embodiment, the composition 20 undergoes a UV-thermal “dual cure.” In this embodiment, the composition 20 comprises a meta-substituted resorcinol epoxy resin (such as RDGE) capable of being thermally latent cured (B-stageable) and a meta-substituted acrylic resorcinol resins or meta-substituted methacrylic-resorcinol resin (such as resorcinol epoxy acrylate or methacrylate) capable of being UV-cured. An amount of free-radical photoinitiator (such as the compounds discussed above) may be added to the composition 20 to assist in UV-curing the meta-substituted acrylic resorcinol resin or meta-substituted methacrylic-resorcinol resin. Additionally, an amount of thermal latent curing agent may be added to the composition 20 to assist in thermally curing the resorcinol epoxy resin (such as an aromatic amine, anhydride, DICY, etc.). The composition 20, including the two types of curing agents, may be partially cured to a tack-free state via UV free-radical polymerization. During this curing step, the resorcinol epoxy resin may remain substantially unpolymerized. The composition 20 may then undergo the final, thermal cure of the epoxy component with heat.

As used herein, an element or step recited in the singular and proceeded with the word “a” or “an” should be understood as not excluding plural elements or steps, unless such exclusion is explicitly recited. Furthermore, references to “one embodiment” of the present disclosure are not intended to be interpreted as excluding the existence of additional embodiments that also incorporate the recited features.

While the present disclosure makes reference to certain embodiments, numerous modifications, alterations and changes to the described embodiments are possible without departing from the sphere and scope of the present disclosure, as defined in the appended claim(s). Accordingly, it is intended that the present disclosure not be limited to the described embodiments, but that it has the full scope defined by the language of the following claims, and equivalents thereof.

1. A corrosion resistant magnetoresistive sensor comprising:
an electrically insulating substrate;
an electrically conductive first terminal disposed on a first end of the substrate;
an electrically conductive second terminal disposed on a second end of the substrate;
a plurality of nanowires disposed on the substrate between the first terminal and the second terminal; and
an oxygen barrier composition covering the nanowires and protecting the nanowires from oxygen and moisture.

2. The corrosion resistant magnetoresistive sensor of claim 1, wherein the nanowires provide an electrically conductive pathway between the first terminal and the second terminal.

3. The corrosion resistant magnetoresistive sensor of claim 1, wherein the nanowires are formed of alternating layers of ferromagnetic and non-magnetic conductive layers.

4. The corrosion resistant magnetoresistive sensor of claim 3, wherein the ferromagnetic conductive layers are formed of a material selected from a group consisting of Co, CoFe, CoNiFe, CoNi, CoNiFeCr, CoCr, CoNiCr, NiFe, NiCo, and NiCoCr.

5. The corrosion resistant magnetoresistive sensor of claim 3, wherein the non-magnetic conductive layers are formed of a material selected from a group consisting of Cu, Ag, Au and alloys of Cu, Ag, and Au.

6. The corrosion resistant magnetoresistive sensor of claim 3, wherein the ferromagnetic conductive layers are less than 100 nanometers in thickness.

7. The corrosion resistant magnetoresistive sensor of claim 3, wherein the non-magnetic conductive layers are less than 50 nanometers in thickness.

8. The corrosion resistant magnetoresistive sensor of claim 1, wherein the nanowires include one or more of giant magnetoresistance (GMR) nanowires, ordinary magnetoresistance (OMR) nanowires, anisotropic magnetoresistance (AMR) nanowires, tunneling magnetoresistance (TMR) nanowires, and colossal magnetoresistance (CMR) nanowires.

9. The corrosion resistant magnetoresistive sensor of claim 1, wherein the oxygen barrier composition includes meta-substituted aromatic resins.

10. The corrosion resistant magnetoresistive sensor of claim 1, wherein the oxygen barrier composition includes an aromatic epoxy resin.

11. The corrosion resistant magnetoresistive sensor of claim 1, wherein the oxygen barrier composition includes a meta-substituted aromatic resin ranging between 1% by weight and 100% by weight of the oxygen barrier composition, and optionally at least one of:
an aromatic epoxy resin ranging between 0.1% by weight and 99% by weight of the oxygen barrier composition; and
a filler ranging between 0.1% by weight and approximately 80% by weight of the oxygen barrier composition.

12. A method of forming a corrosion resistant magnetoresistive sensor, the method comprising:
providing an electrically insulating substrate;
connecting an electrically conductive first terminal to a first end of the substrate;
connecting an electrically conductive second terminal to a second end of the substrate;
disposing a plurality of nanowires on the substrate between the first terminal and the second terminal; and
covering the nanowires with an oxygen barrier composition that protects the nanowires from oxygen and moisture.

13. The method of claim 12, wherein disposing the plurality of nanowires on the substrate comprises suspending the nanowires in a carrier liquid, applying the carrier liquid to the substrate, and evaporating the carrier liquid.

14. The method of claim 12, further comprising curing the oxygen barrier composition.

15. The method of claim 12, wherein the nanowires are formed of alternating layers of ferromagnetic and non-magnetic conductive layers.

16. The method of claim 15, wherein the ferromagnetic conductive layers are formed of a material selected from a group consisting of Co, CoFe, CoNiFe, CoNi, CoNiFeCr, CoCr, CoNiCr, NiFe, NiCo, and NiCoCr.

17. The method of claim 15, wherein the non-magnetic conductive layers are formed of a material selected from a group consisting of Cu, Ag, Au and alloys of Cu, Ag, and Au.

18. The method of claim 12, wherein the oxygen barrier composition includes meta-substituted aromatic resins.

19. The method of claim 12, wherein the oxygen barrier composition includes an aromatic epoxy resin.

20. The method of claim 12, wherein the oxygen barrier composition includes a meta-substituted aromatic resin ranging between 1% by weight and 100% by weight of the oxygen barrier composition, and optionally at least one of:
an aromatic epoxy resin ranging between 0.1% by weight and 99% by weight of the oxygen barrier composition; and
a filler ranging between 0.1% by weight and approximately 80% by weight of the oxygen barrier composition.
